(19) United States
(12) Patent Application Publication
(10) Pub. No.: US 2026/0144016 A1
(43) Pub. Date: May 21, 2026

(54) METHOD FOR LEVELING WAFER

(71) Applicant: OLDOWAN INC., Cheongju-si (KR)

(72) Inventor: Jae Hee SIM, Cheongju-si (KR)

(21) Appl. No.: 19/452,986

(22) Filed: Jan. 20, 2026

Related U.S. Application Data
(63) Continuation of application No. PCT/KR2023/012632, filed on Aug. 25, 2023.

(30) Foreign Application Priority Data
Jul. 20, 2023 (KR) 10-2023-0094561

(51) Int. Cl. H10P 76/20; H10P 95/00

(52) U.S. Cl. CPC H10P 76/204; H10P 95/08

(57) ABSTRACT

A method for wafer planarization according to an embodiment of the present invention comprises: coating a wafer with a coating material; preparing a template that is fixed to an upper chuck and coated with a release agent; introducing the wafer and the upper chuck into a chamber and pressing the coating material on the wafer with the template in a vacuum atmosphere; and releasing the vacuum in the chamber and unloading the upper chuck from the wafer.

### CROSS-REFERENCE TO RELATED APPLICATION(S)

This present application is a Continuation of International Patent Application No. PCT/KR2023/012632, filed on Aug. 25, 2023, which is based upon and claims the benefit of priority to Korean Patent Application No. 10-2023-0094561 filed on Jul. 20, 2023. The disclosures of the above-listed applications are hereby incorporated by reference herein in there entirety.

### TECHNICAL FIELD

The present invention relates to a method for planarizing a wafer, and more particularly, to a method for planarizing a wafer using an imprint technique.

### RELATED ART

As demand for ultra-high integration semiconductors increases, competitiveness in developing new process technologies and related equipment is required. Furthermore, efforts in the semiconductor industry to reduce manufacturing costs by reducing defect occurrence and the number of processes in the manufacturing process are ongoing.

Planarization technology is useful in manufacturing semiconductor devices. For example, a process for producing a semiconductor device includes repeatedly adding and removing material to and from a substrate.

These processes can produce stacked substrates having irregular height variations (i.e., topography), and as more layers are added, the substrate height variations can increase. Height variations negatively affect the ability to add additional layers to the stacked substrate. Separately, the semiconductor substrate (e.g., silicon wafer) itself is not always perfectly flat and may include initial surface height variations (i.e., topography).

One way to solve this problem is to planarize the substrate between stacking steps.

When coating a lower film having a step difference by a conventional spin coating method, a difference in coating thickness occurs between regions with and without the step difference. The difference in coating thickness can cause Not Open defects in subsequent processes.

To solve this problem, additional processes such as a coating process to reduce the lower film step difference, CMP (Chemical Mechanical Polishing), and cleaning are being added, but this ultimately leads to increased manufacturing costs and causes a reduction in cost competitiveness.

Another method for improving flatness is to utilize imprinting lithography technology. This is a method that can secure productivity and price competitiveness by performing a relatively simplified process.

Korean Patent Publication No. 2022-0028124 (published Mar. 8, 2022) entitled “Planarization Process, Apparatus, and Article Manufacturing Method” describes a process for planarizing a wafer. The above publication utilizes a fluid dispenser to deposit droplets of planarization material on the wafer and cures the planarization material through UV curing.

However, according to this process, it is difficult to accurately control the amount of droplets input from the fluid dispenser and difficult to predict the thickness deposited on the wafer. In addition, for UV curing, the upper chuck must be made of a material through which UV light can pass.

### DETAILED DESCRIPTION

### Technical Subject

An object of the present invention is to provide a method for performing wafer planarization through an imprinting lithography process.

Another object is to provide a wafer planarization method capable of improving productivity through a process that is simplified compared to conventional processes.

### Technical Solution

A wafer planarization method according to an embodiment of the present invention includes coating a wafer with a coating material, preparing a template fixed to an upper chuck and coated with a release agent, loading the wafer and the upper chuck into a chamber and pressing the coating material on the wafer with the template in a vacuum atmosphere, and releasing the vacuum in the chamber under the vacuum atmosphere and unloading the upper chuck from the wafer.

The step of coating the wafer with the coating material includes spin coating SOC (Spin On Carbon) on the wafer.

The step of preparing the template fixed to the upper chuck and coated with a release agent includes coating trichlorosilane on the template.

Further, the step of coating trichlorosilane on the template includes preparing a solution by dissolving 0.1 vol % HDFS in N-Hexane, reacting by immersing the template in the solution, washing the reacted template with N-Hexane and washing with DI water, performing ultrasonic cleaning with HFE solution, and washing with DI water and removing surface moisture with N2 gas.

Further, the step of loading the wafer and the upper chuck into the chamber and pressing the coating material on the wafer with the template in the vacuum atmosphere includes heating the SOC to a glass transition temperature.

Particularly, the glass transition temperature may be 100° C. to 200° C.

Further, the step of unloading the upper chuck from the wafer according to an embodiment of the present invention includes lifting an edge of the template in the chamber while releasing the vacuum to separate the coating material and the template.

Further, the wafer planarization method according to an embodiment of the present invention further includes, after the step of separating the coating material and the template, heating the wafer to 400° C.

### Effect

According to the wafer planarization method according to an embodiment of the present invention, wafer planarization is possible with a simple process.

Further, the process time is shortened, thereby improving productivity.

Further, when separating from the upper chuck after pressing the wafer, deformation of the planarization material does not occur, enabling stable process execution.

Further, since the conventional planarization process can be utilized, existing process equipment and materials can be utilized.

Additional scope of applicability of the present invention will become apparent from the detailed description given hereinafter. However, since various changes and modifications within the spirit and scope of the present invention can be clearly understood by those skilled in the art, it should be understood that the detailed description and specific embodiments such as preferred embodiments of the present invention are given by way of illustration only.

### BRIEF DESCRIPTION OF FIGURES

FIG. 1 is a conceptual diagram of a wafer planarization method according to an embodiment of the present invention.

FIG. 2 is a flowchart of a wafer planarization method according to an embodiment of the present invention.

FIG. 3 shows experimental results of quartz glass uniformity as a template and damage depending on pressure applied by the template to the wafer.

FIG. 4 shows test results of insolubility degree according to types of solvents and input concentrations of trichlorosilane according to an embodiment of the present invention.

FIG. 5 is a flowchart of a method for coating trichlorosilane on a template according to an embodiment of the present invention.

### MODE

Specific structural or functional descriptions of embodiments according to the concept of the present invention disclosed in this specification are merely illustrated for the purpose of describing embodiments according to the concept of the present invention, and embodiments according to the concept of the present invention may be implemented in various forms and are not limited to the embodiments described in this specification.

Terms such as first or second may be used to describe various components, but the components should not be limited by the terms. The terms are used only for the purpose of distinguishing one component from another component, and for example, without departing from the scope of rights according to the concept of the present invention, a first component may be referred to as a second component, and similarly, a second component may also be referred to as a first component.

When a component is referred to as being “connected to” or “coupled to” another component, it should be understood that it may be directly connected to or coupled to the other component, but other components may exist in between. On the other hand, when a component is referred to as being “directly connected to” or “directly coupled to” another component, it should be understood that no other components exist in between. Other expressions describing relationships between components, such as “between” and “directly between” or “adjacent to” and “directly adjacent to,” should be interpreted likewise.

The terminology used herein is for the purpose of describing particular embodiments only and is not intended to be limiting of the invention. The singular forms include plural forms unless the context clearly indicates otherwise. In this specification, terms such as “comprise” or “have” are intended to designate that a feature, number, step, operation, component, part, or combination thereof described in the specification is present, and should be understood as not precluding the presence or addition of one or more other features, numbers, steps, operations, components, parts, or combinations thereof.

Hereinafter, embodiments of the present invention will be described in detail with reference to the drawings attached to this specification.

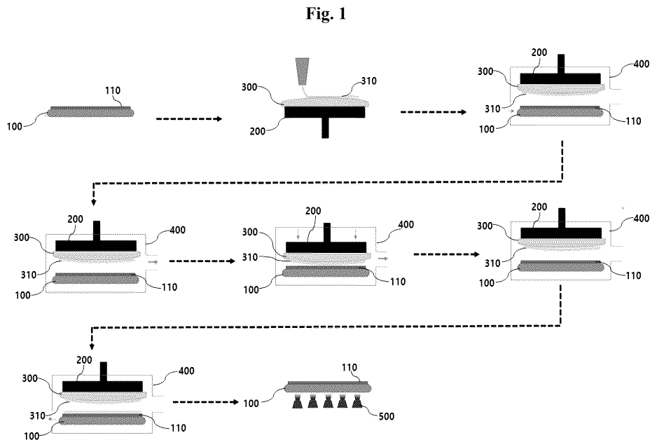

FIG. 1 is a conceptual diagram of a wafer planarization method according to an embodiment of the present invention.

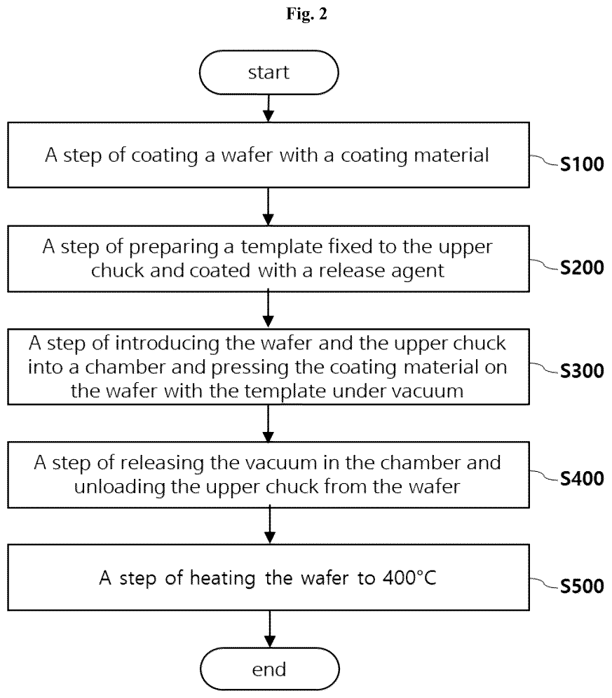

FIG. 2 is a flowchart of a wafer planarization method according to an embodiment of the present invention.

As shown in FIGS. 1 and 2, the wafer planarization method according to an embodiment of the present invention includes: coating a wafer (100) with a coating material (110) (S100); preparing a template (300) fixed to an upper chuck (200) and coated with a release agent (310) (S200); loading the wafer (100) and the upper chuck (200) into a chamber (400) and pressing the coating material (110) on the wafer (100) with the template (300) in a vacuum atmosphere (S300); and releasing the vacuum in the chamber (400) in the vacuum atmosphere and unloading the upper chuck (200) from the wafer (100) (S400).

The step (S100) of coating the wafer (100) with the coating material (110) is a step of spin-coating the coating material (110) on the upper surface of the wafer (100) as shown in FIG. 1. The coating material (110) is SOC (Spin On Carbon hardmask), which is a coating material (110) mainly applied by spin coating in processes where the flatness of the underlying film is an issue.

The characteristics of SOC as the coating material (110) according to an embodiment of the present invention are preferably that it is a material that improves flowability by having a long polymer chain, maintains low viscosity for a long time with a material having a high BP (boiling point), and lowers the glass transition temperature to improve flatness through self-leveling upon heating.

Table 1 below shows the evaluation results of the wafer (100) when the coating material (110) was spray coated or slit coated as in the aforementioned Korean Patent Publication No. 2022-0028124.

TABLE 1

| Type | Evaluation Content | Development Results |
|---|---|---|
| Spray | The conformal coating properties | Step height removal |
| Coating | have been further enhanced. | failure |
| Slit | Significant shrinkage occurs | Step height removal |
| Coating | during baking | failure |

As shown in Table 1, when spray coating and slit coating were performed, removal of step differences formed on the wafer (100) failed.

As shown in FIGS. 1 and 2, the step (S200) of preparing the template (300) fixed to the upper chuck (200) and coated with the release agent (310) is a step of fixing the template (300) to the pre-prepared upper chuck (200) and coating the release agent (310) on the template (300).

The template (300) may be quartz glass, and preferably has a flatness with a uniformity of 0.3 μm or less.

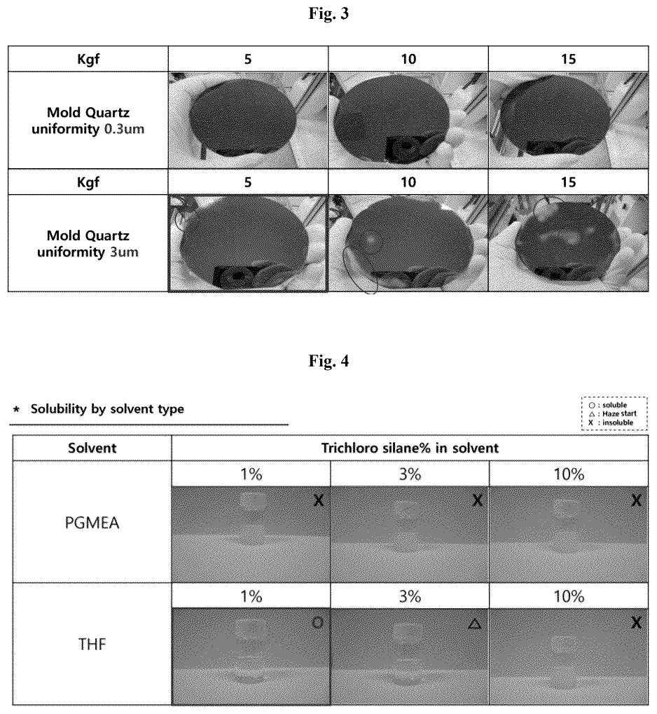

FIG. 3 shows the results of an experiment on damage depending on the quartz glass uniformity of the template (300) and the pressure applied by the template (300) to the wafer (100).

As shown in FIG. 3, when the quartz glass uniformity was 0.3 μm, there was no SOC surface damage due to pressure, and it was found that release characteristics were present.

However, when the quartz glass uniformity was 3 μm, SOC surface damage (indicated by circles) occurred as the pressure increased, and it was found that there were no release characteristics in that external force was applied during separation from the wafer (100).

In the step (S200) of preparing the template (300) coated with the release agent (310) according to an embodiment of the present invention, the release agent (310) includes trichlorosilane. More specifically, trichlorosilane is dissolved using the solvent THF (L-5,6,7,8-tetrahydrofolic acid).

FIG. 4 shows the results of testing the degree of insolubility according to the type of solvent and the input concentration of trichlorosilane according to an embodiment of the present invention.

As shown in FIG. 4, when 1 wt % trichlorosilane was added to THF, no haze occurred and dissolution was observed. When trichlorosilane was added to PGMEA, haze was found to occur at all concentrations of 1%, 3%, and 10%.

In addition, when 3% or 10% trichlorosilane was added to THF, slight haze was also found to occur, indicating that the release agent (310) with 1% trichlorosilane added to THF exhibits the most ideal characteristics.

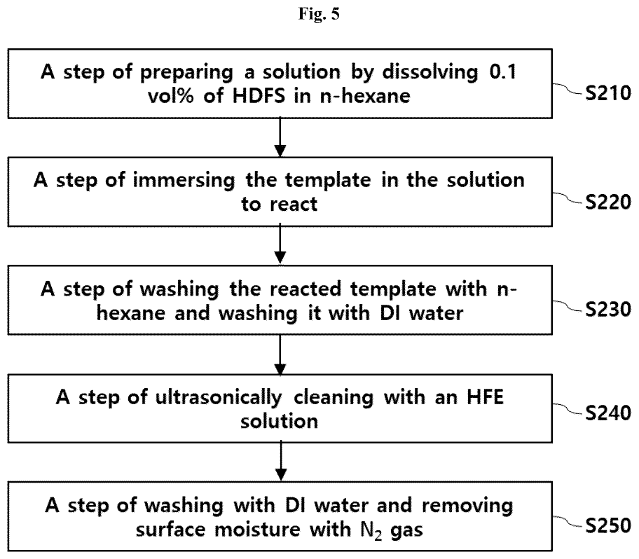

FIG. 5 is a flowchart of a method of coating trichlorosilane on the template (300) according to an embodiment of the present invention.

As shown in FIG. 5, the step (S200) of coating trichlorosilane on the template (300) includes: preparing a solution by dissolving HDFS 0.1 (vol %) in N-Hexane (normal hexane) (S210); reacting by placing the template (300) in the solution (S220); washing the reacted template (300) with n-Hexane and washing with DI water (S230); ultrasonic cleaning with HFE solution (S240); and washing with DI water and removing surface moisture with N&#x2082; gas (S250).

As a method of planarizing the wafer (100) after the step (S200) of preparing the template (300), as shown in FIGS. 1 and 2, the step (S300) of loading the wafer (100) and the upper chuck (200) into the chamber (400) and pressing the coating material (110) on the wafer (100) with the template (300) in a vacuum atmosphere involves placing the wafer (100) at the bottom of the chamber and placing the upper chuck (200) at the top to seal the chamber (400), as shown in FIG. 1. In the sealed state, the air inside the chamber (400) is evacuated to the outside to create a vacuum state.

When placed in a vacuum state, the upper chuck (200) on which the template (300) is mounted descends toward the wafer (100) to press the coating material (110) coated on the wafer (100). In addition, in the pressed state, the SOC coated on the wafer (100) is heated to a glass transition temperature of 100° C. to 200° C.

By heating the SOC, which is the coating material (110) coated on the upper portion of the wafer (100), to the glass transition temperature, the viscosity of the SOC is lowered. The SOC with improved flowability spreads while filling patterns on the surface of the wafer (100).

Next, as shown in FIGS. 1 and 2, the step (S400) of releasing the vacuum in the chamber (400) in the vacuum atmosphere and unloading the upper chuck (200) from the wafer (100) is a step in which the upper chuck (200) rises to separate the template (300) from the SOC.

In this process, the temperature of the SOC decreases and the viscosity increases.

The step (S400) of unloading the upper chuck (200) from the wafer (100) includes separating the coating material (110) and the template (300) by lifting the edge of the template (300) in the chamber (400) while releasing the vacuum. That is, when the edge of the template (300) is physically lifted, inflowing air permeates to separate the template (300) and the coating material (110), and as the upper chuck (200) rises, the template (300) naturally separates from the coating material (110).

Next, as shown in FIGS. 1 and 2, the wafer (100) planarization method according to an embodiment of the present invention further includes heating the wafer (100) to 400° C. with a heater (500) (S500).

This is a process of heating the wafer (100) planarized by the coating material (110) to cause polymers in the coating material (110) to cross-link with each other, transforming into a single carbon mass.

Before undergoing this cross-linking process, the coating material (110) is a polymer, and after undergoing the cross-linking process, it becomes a large carbon mass with unlimited molecular weight, forming a hard layer.

By undergoing the wafer planarization process according to an embodiment of the present invention, wafer planarization is possible by performing a relatively simple process, and process time is shortened accordingly, improving productivity. In addition, a highly reliable wafer planarization method can be provided using coating materials and release agents optimized for the planarization process applying the imprinting process.

The present invention can have various changes and various embodiments, and specific embodiments are illustrated in the drawings and specifically described in the detailed description. However, this is not intended to limit the present invention to specific embodiments, and should be understood to include all modifications, equivalents, and substitutes included in the spirit and technical scope of the present invention.

What is claimed is:

1. A method for wafer planarization, comprising:
(a) coating a wafer with a coating material;
(b) preparing a template that is fixed to an upper chuck and coated with a release agent;
(c) introducing the wafer and the upper chuck into a chamber and pressing the coating material on the wafer with the template in a vacuum atmosphere; and
(d) releasing the vacuum in the chamber and unloading the upper chuck from the wafer.

2. The method of claim 1, wherein step (a) comprises: spin-coating SOC (Spin On Carbon) on the wafer.

3. The method of claim 1, wherein step (b) comprises: coating the template with trichloro silane.

4. The method of claim 3, wherein the step of coating the template with trichloro silane comprises: preparing a solution by dissolving HDFS 0.1 (vol %) in N-Hexane (normal hexane); immersing the template in the solution to allow reaction; washing the reacted template with n-Hexane and DI water; ultrasonic cleaning with HFE solution; and washing with DI water and removing surface moisture with N₂ gas.

5. The method of claim 2, wherein step (c) comprises: heating the SOC to a glass transition temperature.

6. The method of claim 5, wherein the glass transition temperature is 100° C. to 200° C.

7. The method of claim 1, wherein step (d) comprises: separating the coating material from the template by lifting edges of the template in the chamber while releasing the vacuum.

8. The method of claim 1, further comprising after step (d): heating the wafer to 400° C.
